(19) United States
(12) Patent Application Publication
(10) Pub. No.: US 2007/0124658 A1
(43) Pub. Date: May 31, 2007

(54) Acs apparatus and method for viterbi decoder

(75) Inventor: Marcello Caramma, Bracknell (GB)

Correspondence Address: WOLF GREENFIELD & SACKS, P.C., 600 ATLANTIC AVENUE, BOSTON, MA, 02210-2206, US

(73) Assignee: Ubinetics Limited, Hertfordshire (GB)

(21) Appl. No.: 10/555,077

(22) PCT Filed: Apr. 27, 2004
(86) PCT No.: PCT/GB04/01770

§ 371 Date: Jan. 23, 2007

(30) Foreign Application Priority Data
Apr. 29, 2003 (GB) 0309782.1

(51) Int. Cl. H03M 13/03

(52) U.S. Cl. 714/796

(57) ABSTRACT

The circuit (10) performs a butterfly calculation for a Viterbi trellis by using two path metrics and a branch metric to generate two new path metrics. The new metrics are produced by adders (12) and (14) whose inputs are controlled by selectors (16-22). The outputs of the selectors (16-22) are controlled by selection control unit (24) which considers the difference between the given path metrics relative to the double of the branch metric, which represents a branch metric difference.

The invention relates to methods of, and apparatus for, the calculation of metrics for use in, for example, the decoding of convolutionally encoded signals.

A convolutionally encoded signal can be decoded using the Viterbi algorithm.

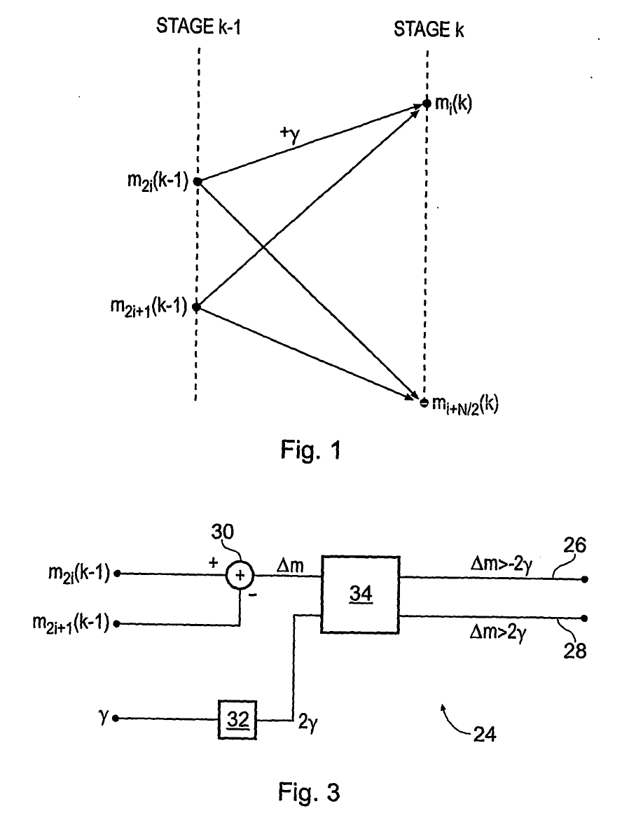

In a decoding process using the Viterbi algorithm, a received signal is represented as a trellis of states and path metrics are calculated recursively for the states in the trellis by using branch metrics to move between the states. FIG. 1 illustrates a butterfly calculation showing how, in Viterbi decoding, path metrics mᵢ and m_{i+N/2} are calculated for the k^{th} stage of a trellis from path metrics m₂ᵢ and m₂ᵢ₊₁ of the k−1^{th} stage of the trellis using the branch metric γ between the k^{th} and the k−1^{th} stages. As is well known, each of the k^{th} stage path metrics calculated in the illustrated butterfly calculation is determined using two k−1^{th} stage path metrics in an add/compare/select (ACS) operation.

One aim of the invention is to improve the manner in which ACS operations are performed.

According to one aspect, the invention provides a method of calculating a first new path metric from two old path metrics and a branch metric, the method comprising: determining the difference between the two old path metrics; performing a first comparison of the branch metric and said difference; selecting, on the basis of said first comparison, one of the old path metrics for a first combination with the branch metric; and selecting, on the basis of said first comparison, whether said first combination is by addition or subtraction.

The invention also consists in apparatus for calculating a first new path metric from two old path metrics and a branch metric, the apparatus comprising: subtracting means for determining the difference between the old path metrics; comparing means for performing a first comparison of the branch metric and said difference; and selecting means for selecting, on the basis of said first comparison, one of the old path metrics for a first combination with the branch metric and for selecting, on the basis of said first comparison, whether said first combination is by addition or subtraction.

By calculating path metrics in this fashion, relatively few operations are required thus providing the possibilities of enhancing the speed of operation of, and reducing the silicon area required for, hardware that is configured to calculate path metrics.

In certain embodiments, a second new path metric is calculated from the old path metrics and the branch metric on the basis of a second comparison of the branch metric with the difference in the old path metrics.

In some embodiments, the comparison that controls the calculation of a new path metric is the determination of which is the larger of the difference in the old path metrics and double the branch metric or which is the larger of the difference in the old path metrics and minus double the branch metric.

In some embodiments, comparisons between the difference in the old path metrics and the branch metric involve inspecting the signs of the quantities to be compared to see if the result of the comparison can be deduced from said signs or whether the result of the comparison needs to be calculated from said difference and said branch metric.

The invention is also applicable to decoding schemes other than the Viterbi algorithm, where butterfly calculations may be used. For example, the invention can be used in log-MAP decoding processes.

From a further perspective, the invention also relates to computer programmes, conveyed on a suitable storage device or otherwise, for performing metric calculation methods according to the invention.

By way of example only, an embodiment of the invention will now be described with reference to the accompanying figures, in which:

FIG. 1 illustrates metric calculations forming a butterfly calculation;

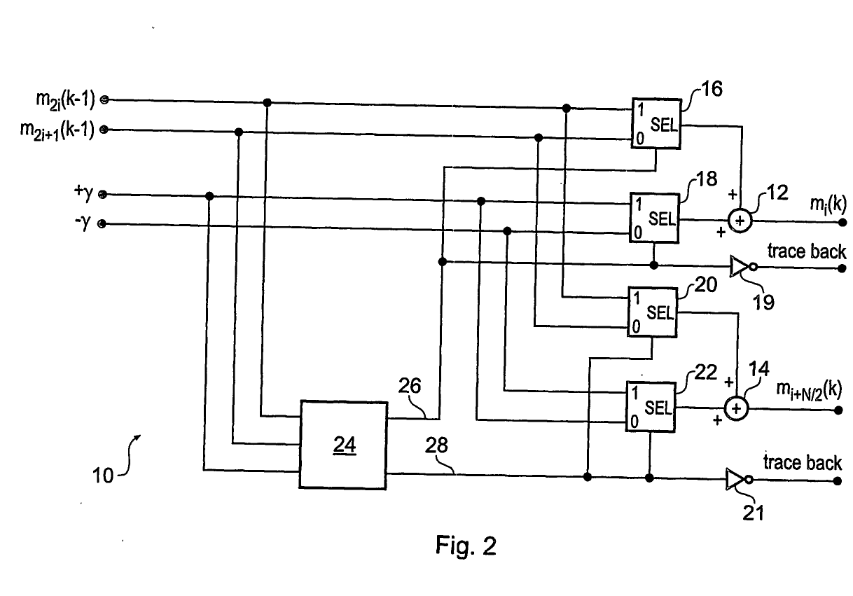

FIG. 2 illustrates a circuit for performing ACS operations;

FIG. 3 illustrates the selector control unit of the circuit of FIG. 2 in more detail;

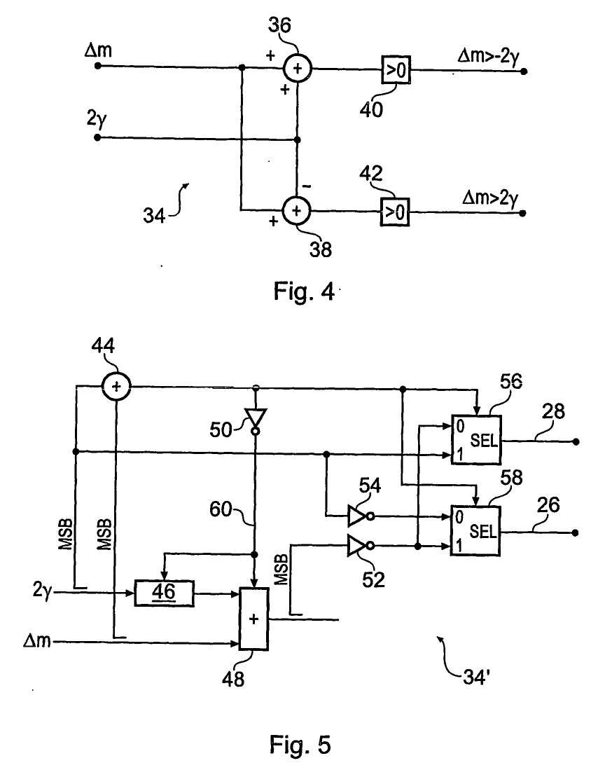

FIG. 4 illustrates the comparison unit of FIG. 3 in more detail; and

FIG. 5 illustrates an alternative circuit that can be used for the comparison unit of FIG. 3.

In FIG. 1, mᵢ(k) is the greater of [m₂ᵢ(k−1)+γ] and [m₂ᵢ₊₁(k−1)−γ]. The condition of the former quantity being greater than the latter can be expressed as the inequality:
m₂ᵢ(k−1)−m₂ᵢ₊₁(k−1)=Δm>−2γ -inequality 1.

Similarly, m_{i+N/2} (k) is the greater of [m₂ᵢ₊₁(k−1)−γ] and [m₂ᵢ(k−1)+γ] and the condition of the former quantity being greater than the latter can be re-expressed as the inequality:
Δm>2γ -inequality 2.

FIG. 2 illustrates a circuit 10 for producing the metrics mᵢ(k) and m_{i+N/2} (k) from metrics m₂ᵢ(k−1) and m₂ᵢ₊₁(k−1) by performing 2 ACS operations in parallel. The circuit 10 comprises two adders 12 and 14, four selectors 16, 18, 20 and 22 and a selector control unit 24. The inputs to the circuit 10 are the path metrics m₂ᵢ(k−1) and m₂ᵢ₊₁(k−1), the branch metric γ leading from trellis stage k−1 and to trellis stage k a negative version of the branch metric, −γ. These four inputs are variously supplied to the selector units 16, 18, 20 and 22 and the two path metrics and γ are used as inputs for the selector control unit 24.

Each of the selector units 16, 18, 20 and 22 receives two of the inputs to the circuit and, under the control of a selection signal provided by the selector control unit, passes one of its two inputs to its output. The inputs to selector unit 16 are the two path metrics. Selector unit 20 has the same inputs. The branch metric γ and the negative version of the branch metric are the two inputs to selector unit 18. Selector unit 22 has the same inputs as selector unit 18. The outputs of selector unit 16 and 18 are added together at adder 12 and the outputs of selector units 20 and 22 are added together at adder 14.

The inputs to the two adders are dictated by the control signals that are supplied to the four selector units. Selector units 16 and 18 are driven by the same control signal 26 and selector units 20 and 22 are likewise driven by a common control signal 28. Each of the control signals 26 and 28 can take only the logical values 1 and 0. The data inputs to the selectors 16, 18, 20 and 22 are all marked either 1 or 0. If the control input to a selector has the value logical 1, then the data input of the selector that is marked 1 is passed to the output of the selector. Otherwise, when the control signal of a selector has the value logical 0, the data input of the selector that is marked logical 0 is passed to the output of the selector.

The output of adder 12 is the metric mᵢ(k) and takes the value of one of the input path metrics summed with either the positive or negative version of the branch metric, depending upon the value of control signal 26. Control signal 26, after passing through NOT gate 19, also provides an item of traceback data for the calculation of metric mᵢ(k). The output of adder 14 is the metric m_{i+N/2}(k) and again takes the value of one of the input path metrics summed with either the positive or the negative version of the branch metric, depending upon the value of control signal 28. Control signal 28, after passing through NOT gate 21, also provides an item of traceback data for the calculation of metric m_{i+N/2}(k). The production of the control signals 26 and 28 will now be described with reference to FIG. 3, which shows the selector control unit 24 in more detail.

As shown in FIG. 3, the selector control unit 24 comprises an adder 30, configured to perform subtraction, a bit shifter 32 and a comparison unit 34. It will be recalled that the three inputs to the selector control unit 24 are the two input path metrics and the branch metric γ. The two path metrics are supplied as the inputs to adder 30 whose output is then the difference in the two path metrics, Δm, as defined in inequalities 1 and 2. The branch metric γ is supplied to bit shifter 32 which moves the bits in the word representing γ one by place in the direction of increasing significance and appends a zero at the least significant end of the word. In this way, shifter 32 doubles the value of γ.

The quantities Δm and 2γ are supplied to comparison unit 34 in order to test the inequalities 1 and 2. The outputs of the comparison unit 34 are the control signals 26 and 28 for controlling the selector units of FIG. 1. Control signal 26 is the result of inequality 1 and control signal 28 is the result of inequality 2. The control signals 26 and 28 take the value of logical 1 if their respective inequalities are true on the basis of the inputs to the selector control unit 24 and the value of control signals 26 and 28 are logical 0 if their respective inequalities are false.

FIG. 4 shows the construction of the comparison unit 34. The comparison unit 34 comprises two adders 36 and 38 and two check units 40 and 42. The two inputs to the comparison unit 34, Δm and 2γ, are both supplied to each of the two adders 36 and 38. Adder 36 outputs a signal representing the quantity Δm+2γ. The adder 38 is configured to perform the subtraction Δm−2γ. The check units 40 and 42 each evaluate whether the output of their preceding adder is greater than zero. The implementation used for the check units 40 and 42 will depend upon the convention used to represent binary numbers within the system. For example, the check units 40 and 42 may simply evaluate the state of a sign bit of their respective input words. It will be apparent that the output of check unit 40 indicates whether inequality 1 is true or false and that the output of check unit 42 indicates whether or not inequality 2 is true or false.

FIG. 5 shows an alternative construction 34′ that can be used for the comparison unit within the selector unit 24. The inputs to the comparison unit 34′ are still 2γ and Δm and these signals are again used to produce the two control signals 26 and 28 that indicate whether or not inequalities 1 and 2 are true or false.

The comparison unit 34′ comprises an exclusive-or (XOR) gate 44, a multi-bit XOR gate 46, an adder 48, three NOT gates 50, 52 and 54 and two selectors 56 and 58. The input Δm is supplied to one of the inputs of the adder 48. The input 2γ is supplied to an input of the multi-bit XOR gate 46. The other input of the multi-bit XOR gate 46 is a single-bit control signal 60. The multi-bit XOR gate 46 performs a bitwise XOR operation on the word 2γ and the single bit control signal 60. That is to say, multi-bit XOR gate 46 multiplies each bit of the word 2γ with the single-bit control signal 60 to produce a resultant word which is supplied to the other input of adder 48. The control signal 60 is also supplied to a “carry-in” input of the adder 48.

The most significant bits (MSBs) of the inputs 2γ and Am are combined at XOR gate 44. The values Δm and 2γ are in twos complement format such that their MSBs are sign bits with logical 1 indicating a negative number and logical 0 indicating a positive number. The output of XOR gate 44 is logical 1 if the values Δm and 2γ have opposite signs and is logical 0 otherwise.

The output of the XOR gate 44 is used to control selectors 56 and 58. Each of the selectors 56 and 58 has a pair of data inputs. One of the data inputs in each pair is marked 1 and the other data input is marked 0. When the output of XOR gate 44 has the value logical 1, the selectors 56 and 58 transfer to their outputs the signals applied to their inputs that are marked 1. If the output of XOR gate 44 has the value logical 0, then the selectors 56 and 58 transfer to their outputs the signals applied to their inputs that are marked 0. The outputs of the selectors 56 and 58 constitute the control signals 26 and 28 respectively.

In addition to being used to control the selectors 56 and 58, the output of the XOR gate 44 is passed through NOT gate 50 to produce control signal 60. The control signal 60 causes the adder 48 to calculate the value Δm+2γ or Δm−2γ depending upon whether the control signal 60 has the value logical 0 or logical 1 respectively. The multi-bit XOR gate 46 has no effect on 2γ when the control signal 60 has the value logical 0. Likewise, the control signal 60 does not affect the operation of the adder 48 when it has the state logical 0. When the control signal 60 has the state logical 1, the output of the multi-bit XOR gate 46 is a twos complement word whose algebraic equivalent is −2γ−1. The adder 48 adds this quantity to Am but, because the “carry-in” input is now logical 1, the overall calculation performed by the adder 48 is (algebraically) −2γ−1+Δm+1=Δm−2γ. Thus, the multi-bit XOR gate 46 and the adder 48 work together under aegis of control signal 60 to calculate the sum Δm+2γ or Δm−2γ.

Because the twos complement convention is being used for representing binary numbers in the circuit, the MSB of the result of adder 48 is a sign bit which has the value logical 1 if the adder result is negative and otherwise has the value logical 0. The MSB of the result of adder 48 is then passed through NOT gate 52 to provide an input for terminal “0” of selector 56 and an input for the terminal “1” of selector 58. Terminal “1” of selector 56 is supplied with the MSB of Δm. The MSB of Δm is also passed through NOT gate 54 to input for terminal “0” of selector 58. The output of selector 58 is control signal 26 and has the value logical 1 when inequality 1 is true and logical 0 when the inequality is false. The output of selector 56 is control signal 28 and has the value logical 1 when inequality 2 is true and logical 0 when the inequality is false.

Th following truth tables describe the circuit of FIG. 5:

| MSB of 2γ | MSB of Δm | Output | | Output |
|---|---|---|---|---|
| or | or | of | Output of | of |
| 2γ < 0? | Δm < 0? | XOR 44 | NOT 60 | Adder 48 |
| 1 | 1 | 0 | 1 | Δm − 2γ |
| 1 | 0 | 1 | 0 | Δm + 2γ |
| 0 | 1 | 1 | 0 | Δm + 2γ |
| 0 | 0 | 0 | 1 | Δm − 2γ |

| MSB of 2γ | MSB of Δm | Output | Input | Output |
|---|---|---|---|---|
| or | or | of | of | of |
| 2γ < 0? | Δm < 0? | Adder 48 | NOT 52 | NOT 52 |
| 1 | 1 | Δm − 2γ | (Δm − 2γ) < 0? | (Δm − 2γ) > 0? |
| 1 | 0 | Δm + 2γ | (Δm + 2γ) < 0? | (Δm + 2γ) > 0? |
| 0 | 1 | Δm + 2γ | (Δm + 2γ) < 0? | (Δm + 2γ) > 0? |
| 0 | 0 | Δm − 2γ | (Δm − 2γ) < 0? | (Δm − 2γ) > 0? |

| MSB of 2γ | MSB of Δm | Output | Signal 28 | Signal 26 |
|---|---|---|---|---|
| or | or | of | or | or |
| 2γ < 0? | Δm < 0? | XOR 44 | Δm > 2γ? | Δm > −2γ? |
| 1 | 1 | 0 | (Δm − 2γ) > 0? | 0 |
| 1 | 0 | 1 | 1 | (Δm + 2γ) > 0? |
| 0 | 1 | 1 | 0 | (Δm + 2γ) > 0? |
| 0 | 0 | 0 | (Δm − 2γ) > 0? | 1 |

1. A method of calculating a first new path metric from two old path metrics and a branch metric, the method comprising: determining the difference between the two old path metrics; performing a first comparison of the branch metric and said difference; selecting, on the basis of said first comparison, one of the old path metrics for a first combination with the branch metric; and selecting, on the basis of said first comparison, whether said first combination is by addition or subtraction.

2. A method according to claim 1, wherein said first comparison comprises determining whether the result of the first comparison can be determined from the signs of said difference and said branch metric or whether the result of the first comparison needs to be calculated from said difference and said branch metric.

3. A method according to claim 1 or 2, further comprising storing the outcome of the first comparison for use as an item of trace-back information.

4. A method according to claim 1, 2 or 3, wherein said first comparison comprises determining which is the larger of said difference and double the branch metric.

5. A method according to any one of claims 1 to 4, further comprising calculating a second new path metric from the two old path metrics and the branch metric by: performing a second comparison of the branch metric-and said difference; selecting, on the basis of said second comparison, one of the old path metrics for a second combination with the branch metric; and selecting, on the basis of said second comparison, whether said second combination is by addition or subtraction.

6. A method according to claim 5, wherein said second comparison comprises determining whether the result of the second comparison can be determined from the signs of said difference and said branch metric or whether the result of the second comparison needs to be calculated from said difference and said branch metric.

7. A method according to claim 5 or 6, further comprising storing the outcome of the second comparison for use as an item of trace-back information.

8. A method according to claim 5, 6 or 7, wherein said second comparison comprises determining which is the larger of said difference and minus double the branch metric.

9. A method according to claim 1, 2 or 3, wherein said first comparison comprises determining which is the larger of said difference and minus double the branch metric.

10. Apparatus for calculating a first new path metric from two old path metrics and a branch metric, the apparatus comprising: subtracting means for determining the difference between the old path metrics; comparing means for performing a first comparison of the branch metric and said difference; and selecting means for selecting, on the basis of said first comparison, one of the old path metrics for a first combination with the branch metric and for selecting, on the basis of said first comparison, whether said first combination is by addition or subtraction.

11. Apparatus according to claim 10, wherein said comparing means is arranged to determine whether the result of the first comparison can be determined from the signs of said difference and said branch metric or whether the result of the first comparison needs to be calculated from said difference and said branch metric.

12. Apparatus according to claim 10 or 11, further comprising storage means for storing the outcome of the first comparison for use as an item of trace-back information.

13. Apparatus according to claim 10, 11 or 12, wherein said first comparison comprises determining which is the larger of said difference and double the branch metric.

14. Apparatus according to any one of claims 10 to 13, wherein said apparatus is arranged to calculate a second new path metric from said old metrics and said branch metric, said comparing means is arranged to perform a second comparison of the branch metric and said difference and the selecting means is arranged to select, on the basis of said second comparison, one of the old path metrics for a second combination with the branch metric and is arranged to select, on the basis of said second comparison, whether said second combination is by addition or subtraction.

15. Apparatus according to claim 14, wherein said comparing means is arranged to determine whether the result of the second comparison can be determined from the signs of said difference and said branch metrics or whether the result of the first comparison needs to be calculated from said difference and said branch metric.

16. Apparatus according to claim 14 or 15, further comprising storage means for storing the outcome of the second comparison for use as an item of trace-back information.

17. Apparatus according to claim 14, 15 or 16, wherein said second comparison comprises determining which is the larger of said difference and minus double the branch metric.

18. Apparatus according to claim 10, 11 or 12, wherein said first comparison comprises determining which is the larger of said difference and minus double the branch metric.

19. A program for causing data processing apparatus to perform a method according to any one of claims 1 to 9.

20. A method of calculating one or more new path metrics from two old path metrics and a branch metric, the method being substantially as hereinbefore described with reference to the accompanying figures.

21. Apparatus for calculating one or more new path metrics from two old path metrics and a branch metric, the apparatus being substantially as hereinbefore described with reference to the accompanying figures.
